(19) United States
(12) Patent Application Publication
(10) Pub. No.: US 2005/0078123 A1
(43) Pub. Date: Apr. 14, 2005

(54) Method for creating and using text objects as control devices

(76) Inventor: Denny Jaeger, Oakland, CA (US)

Correspondence Address: Wilson & Ham;PMB: 348, 2530 Berryessa Road, San Jose, CA, 95132, US

(21) Appl. No.: 10/952,420

(22) Filed: Sep. 28, 2004

Related U.S. Application Data
(60) Provisional application No. 60/506,815, filed on Sep. 28, 2003.

(51) Int. Cl. H03G 3/00

(52) U.S. Cl. 345/619

(57) ABSTRACT

A method for creating and using a text control allows a user to create a text object that can control one or more control devices, such as faders and knobs, and/or control one or more continuously variable property of some other entity. In an embodiment, the text control may be created by entering “known” characters into a computer environment to produce a text object and then associating the text object to one or more signal sources and/or one or more control devices, such as faders. In another embodiment, the text control may be created by entering any characters into a computer environment and then associating the text object to one or more control devices.

### REFERENCE TO RELATED APPLICATION

This application claims the benefit of U.S. provisional patent application Ser. No. 60/506,815, filed Sep. 28, 2003, the disclosure of which is incorporated herein by reference.

### FIELD OF THE INVENTION

The invention relates generally to computer operations, and more particularly to a method for creating and using control devices in a computer operating environment.

### BACKGROUND OF THE INVENTION

Graphic control devices, such as faders, buttons and dials, used in various computer applications are usually programmed to perform predefined functions. As an example, an audio player application may include a volume control fader, a balance control fader, a bass control fader and a treble control fader. The functions of these faders are programmed and usually cannot be changed by a user. Thus, a volume control fader usually cannot be changed to control, for example, the bass. Similarly, the scaling resolutions of these faders are programmed and usually cannot be increased or decreased.

In some computer applications, the functionalities of graphic control devices may be modified by the user. However, the modification of these functionalities typically involves navigating through one or more menus to find the appropriate commands. For a novice user of these programs, finding these commands could be a challenging task. Furthermore, the location of these commands for modifying the graphic control devices usually varies from one application to the next. Thus, a user who is familiar with one application may have to become familiar with another application to modify the graphic control devices in that latter application. In addition, the modification of control devices is usually limited in that one modified control device generally cannot easily be made to control another control device. Furthermore, all of the above-described controls need labels of some kind in order to be operated. These labels take up space and are rarely user-definable.

In view of these disadvantages, what is needed is a method for creating and using control devices that is easy to execute by any user, even a novice user.

### SUMMARY OF THE INVENTION

A method for creating and using a text control allows a user to create a text object that can control one or more control devices, such as faders and knobs, control one or more signal sources, such as sound files or video files, and/or control some property of some other entity such as the width of a rectangle or the rate of flow of widgets in a widget factory. In an embodiment, the text control may be created by entering “known” characters into a computer environment to produce a text object and then associating the text object to one or more signal sources and/or one or more control devices, such as faders. In another embodiment, the text control may be created by entering any characters into a computer environment and then associating the text object to one or more control devices.

A method for creating and using a control text object in accordance with an embodiment of the invention comprises providing a text object and a graphic object in a computer environment, drawing a graphic directional indicator in the computer environment, including associating the text object and the graphic object with the graphic directional indicator, activating a transaction assigned to the graphic directional indicator, and assigning a function to the text object such that the text object can be used to control an operation associated with the graphic object.

An embodiment of the invention includes a storage medium, readable by a computer, tangibly embodying a program of instructions executable by the computer to perform method steps for creating and using a control text object.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 depicts the creation of a text control using “known” text and the “send to” arrow logic in accordance with an embodiment of the invention.

FIG. 2 depicts the creation of a Word Control using the “word control” arrow logic in accordance with an embodiment of the invention.

FIG. 3A depicts a “volume” Word Control with invisible switches over the word control text characters in accordance with an embodiment of the invention.

FIG. 3B depicts a “volume” Word Control with invisible switches under the word control text characters in accordance with an embodiment of the invention.

FIG. 4A depicts an Info Canvas object for a “volume” Word Control in accordance with an embodiment of the invention.

FIG. 4B depicts an Info Canvas object for a “bright” text control in accordance with an embodiment of the invention.

FIG. 5 is a flowchart of the process of creating a text control in accordance with an embodiment of the invention.

FIG. 6 is a flowchart of the process of creating a Word Control with invisible switches placed under the word control text characters in accordance with an embodiment of the invention.

FIG. 7 is a flowchart of the process of setting up a Word Control with invisible switches placed under the word control text characters in accordance with an embodiment of the invention.

FIG. 8 is a flowchart of the process of using a Word Control with invisible switches placed under the word control text characters in accordance with an embodiment of the invention.

FIG. 9 is a flowchart of the process of creating a Word Control with invisible switches placed over the word control text characters with a space between the two switches in accordance with an embodiment of the invention.

FIG. 10 is a flowchart of the process of setting up a Word Control with invisible switches placed over the word control text characters in accordance with an embodiment of the invention.

FIG. 11 is a flowchart of the process of using a Word Control with invisible switches placed over the word control text characters in accordance with an embodiment of the invention is described.

FIG. 12 is a flowchart of the process of creating a Word Control without invisible switches in accordance with an embodiment of the invention.

FIG. 13 is a flowchart of the process of setting up a Word Control without invisible switches in accordance with an embodiment of the invention.

FIGS. 14A and 14B show a flowchart of the process for drawing an arrow in Blackspace environment and applying an arrow logic in accordance with an embodiment of the invention is now described.

FIG. 15 is a process flow diagram of a method for creating and using a control text object in accordance with an embodiment of the invention.

### DETAILED DESCRIPTION

A method for creating and using text controls in accordance with an embodiment of the invention allows a user to create a text object that can control one or more control devices, such as faders, knobs, and the like, or control one or more signal sources, such as sound files. The benefits of using a text object as a control device (referred to herein as the “text control” or “word control”) include the following:

A. A text control typically takes up less onscreen space than a fader, knob, joystick or other control devices.

B. A text control utilizes text which can describe the very process that it is controlling.

C. A text control is both an easy and a familiar control for those not familiar with various control devices, e.g., faders, knobs, joysticks and the like.

D. If a text control controls a control device, e.g., a fader, and that fader controls a function of a DSP or other type of functional device, this text control, ends up controlling that function. This means that text controls can control any type of signal processing that a system supports.

In an exemplary embodiment, the method in accordance with the invention is executed by software installed and running in a computer. Thus, the method is sometimes referred to herein as the “software”. The method is described herein with respect to a computer operating environment referred to as the “Blackspace” environment. However, the invention is not limited to the Blackspace environment and may be implemented in a different computer operating environment. The word “Blackspace” is a trademark of the NBOR Corporation. The Blackspace environment presents one universal drawing surface that is shared by all graphic objects within the environment. The Blackspace environment is analogous to a giant drawing “canvas” on which all graphic objects generated in the environment exist and can be applied. Thus, the Blackspace environment is sometimes referred to herein as the Blackspace surface. Each of these graphic objects can have a user-created relationship to any or all the other objects. There are no barriers between any of the objects that are created for or exist on this canvas. Users can create objects with various functionalities without delineating sections of screen space.

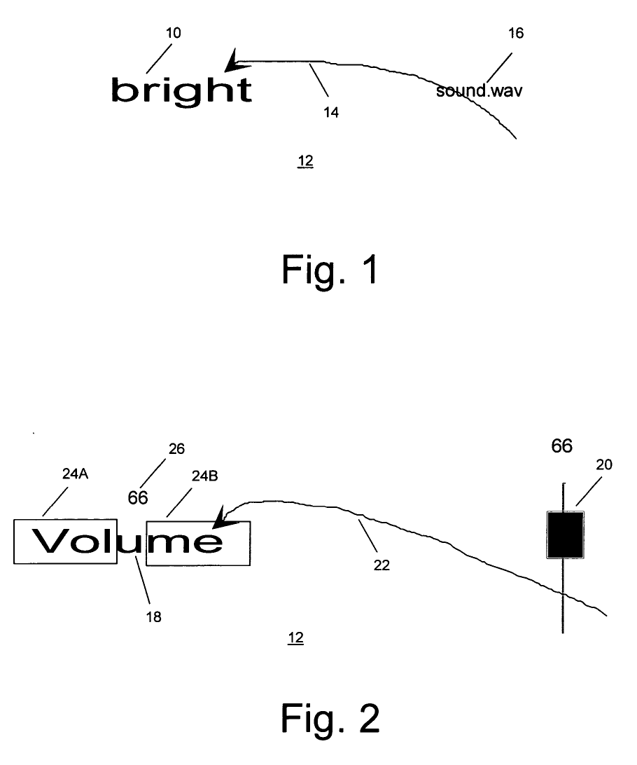

In an embodiment, digital signal processing (DSP) functions or any other function can be assigned to a text object containing predefined or known text. These DSP functions may include various types of signal processing. One example is the bright control. To implement this control, as shown in FIG. 1, a user would type the word “bright” 10 onscreen in a Blackspace environment 12 and hit the Esc key or its equivalent. The word “bright” 10 will be recognized as a predefined or known text for bright control and the text object “bright” is transformed into a bright control. When the bright control is created, the text object 10 may change in appearance to indicate that the text object is now a bright control. For example, the actual text may turn bold and change to red.

After a text control is created, multiple signal sources (e.g., sound files), and/or control devices (e.g., sound switches or faders with sounds or sound switches assigned) can be connected to this text control. Thus, any audio source or audio control device can be connected to the “bright” text control 10 of FIG. 1. The connection can be made using an arrow logic by drawing an arrow of a particular color, e.g., gray, that intersects, nearly intersects or encircles (“intersects”) one or more signal sources and/or control devices with the head of the arrow pointed to a text control.

In FIG. 1, a gray arrow 14 is drawn that intersects a sound file “sound.wav” 16 with the head of the gray arrow pointed to the “bright” text control 10. After the arrow 14 is drawn, the arrowhead of the arrow turns white or its equivalent to indicate that the software recognizes a valid context for the drawn arrow. Then the user would touch the white arrowhead of this arrow and the connection is made from the sound source, i.e., “sound.wav” 16, to the bright control, i.e., the “bright” text object 10.

The arrow logic utilized for this operation is called a “send to” arrow logic. It is generally assigned to the gray colored arrow. This arrow logic can be represented in a sentence as follows: “the item(s) that the arrow is drawn from are sent to the item(s) that the arrow points to.” In this case, the item that the arrow is drawn from is a sound source and the item that the arrow is pointing to is a text control called “bright”. This process enables users to type known text onscreen and have this text actuate DSP processes, and furthermore, be able to “hook up” a signal source, e.g., a .wav sound file, to the input of this DSP device by simply drawing a gray “send to” arrow from the signal source with the arrowhead pointed to or intersecting the “bright” text control.

NOTE: For more information pertaining to arrow and arrow logics please refer to pending U.S. patent application Ser. No. 09/880,397, filed Jun. 12, 2001, entitled “Arrow Logic System for Creating and Operating Control Systems”, and pending U.S. patent application Ser. No. ______, filed Sep. 13, 2004, entitled “Method for Creating User-Defined Computer Operations Using Arrows”, which are both incorporated herein by reference.

To operate this “bright” text control 10, a user would left-click on the left side of the “bright” text object to decrease the brightness (high frequency content) of the sound source being sent to the DSP controlled by the text control, or left-click on the right side of the text control to increase the high frequency content of this same sound source.

When the “bright” text control 10 is being used, the text “bright” can change its color for each increase or decrease in brightness. In this manner a user can see a visual indication of the increases or decreases in DSP control afforded by the text control 10. Generally, the word “bright” gets progressively lighter in color as the brightness increases and gets progressively darker in color as the brightness decreases, but any combination is possible. In addition, any DSP process supported by the system can be designated for any text control. This can be accomplished in software as an embedded behavior for that text control or a user could make a selection in a menu or Info Canvas object among various possible DSP devices to be assigned to a specific text control or a user could draw an arrow between the text control and the object or function to be assigned to the text control.

The construction of a text control such as the “bright” text control 10 and the operation of the text control are described in more detail below.

In another embodiment, a text control can be created using any text object and a “word control” arrow logic. This arrow logic can be represented in a sentence as follows: “The function(s) of the device that the arrow is drawn from is assigned to a text object such that the repeated touching the right end of the text object or the left end of the text object changes the value settings of the device.” For example, if a fader, which is controlling the rotation of an object, is assigned to a text object, repeated clicking on the right side of the text object could progressively cause the rotation of the object in a clockwise direction, while repeated clicking on the left side of the text object could progressively cause the rotation of the object in a counter-clockwise direction or vice versa. This arrow logic may be invoked using a magenta arrow. Thus, this arrow logic is sometimes referred to herein as the “magenta” arrow logic.

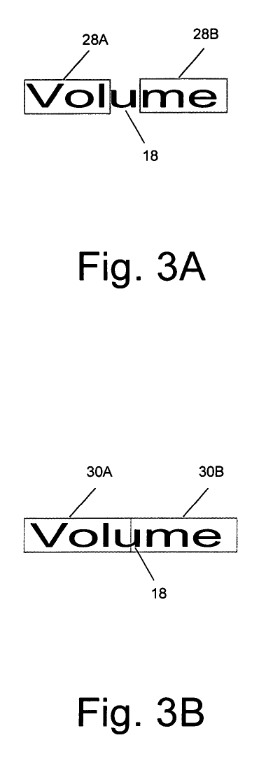

The creation of a text control using the “word control” arrow logic is described using an example illustrated in FIG. 2. As shown in FIG. 2, a text object 18 containing the text “volume” is entered into the Blackspace environment 12, e.g., by typing “volume” on the screen. In addition, a fader 20 is created in the Blackspace environment 12. The fader 20 may be created using a recognition feature of the Blackspace environment 12, which creates a fader when a straight line that is intersected by a half a circle is drawn. Alternatively, the fader 20 may already exist in the Blackspace environment 12. The fader 20 may be configured to control some function, action, property or the like. In this example, the fader 20 is configured to control volume.

A magenta arrow 22 is then drawn to intersect the fader 20 with the arrowhead pointed to the “volume” text object 18. After drawing the arrow 22, if the software recognizes the drawing of the arrow, which has the “word control” arrow logic designated for it, and if this arrow (as drawn) has a valid source object and target object, the head of the magenta arrow will turn color (e.g., white) or have some other appropriate graphic applied to it to visibly change its state. Other possibilities for this graphic would be pulsing the arrowhead, or flashing it, or changing it to another color, etc. When the user clicks on the arrowhead, the “word control” arrow logic is implemented and the “volume” text object 18 is replaced with a word control, with the text “volume” configured to control the fader 20 and thus can control volume. Furthermore, the dimensions of the text “volume” are analyzed and two graphical areas within the text characters of the “volume” word control are created, a right-hand area 24A and a left-hand area 24B. These two areas 24A and 24B of the “volume” word control 18 allow a user to manipulate the word control to control the fader 20. When the “volume” word control 18 receives a left click event from the mouse handling software, it could work out that it was within one of these two areas 24A and 24B and cause the corresponding fader change.

In addition, a smaller piece of text 26 may be created near the “volume” word control 18, as shown in FIG. 2. This text 26 shows the value of the fader 20 and may also show the unit for this value, e.g., db. As the fader 20 is changed, this text value changes accordingly. Furthermore, as the “volume” word control 18 is operated by clicking the right-hand area 24A or the left-hand area 24B of the word control, the fader's value changes accordingly. In this example, the left-hand area 24A of the “volume” word control 18 is used to decrease the volume, and the right-hand area 24B of the word control is used to increase the volume, but these operations could be reversed.

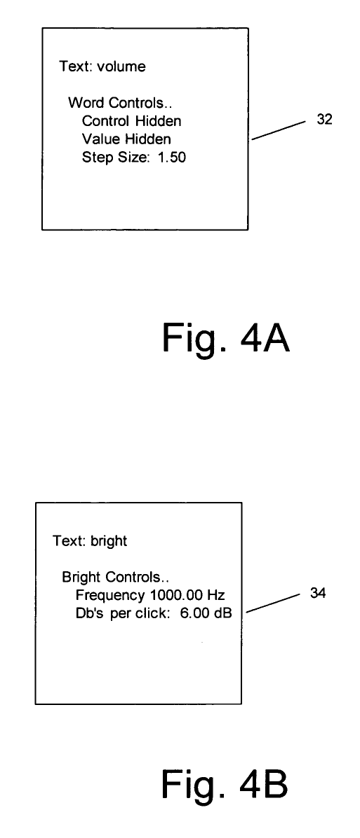

In an embodiment, the left-hand and right-hand areas 24A and 24B of the “volume” text control 18 are implemented as invisible switches 28A and 28B over the text characters, as shown in FIG. 3A. These invisible switches 28A and 28B are positioned such that the switches do not meet in the middle of the text object. Instead, a small space is allotted, which may be about the width of a single text character. This space is used to enable a user to right-click on the character(s) under the switches in order to gain access to the Info Canvas object for these characters. An Info Canvas object includes various entries for modifying properties or behaviors of a graphic object to which it belongs. The word “Info Canvas” is a trademark of the NBOR Corporation. For more information on Info Canvas objects, see U.S. patent application Ser. No. 10/635,742, filed on Aug. 5, 2003, entitled “Intuitive Graphic User Interface with Universal Tools”, U.S. patent application Ser. No. 10/671,953, filed on Sep. 26, 2003, entitled “Intuitive Graphic User Interface with Universal Tools”, and PCT patent application no. PCT/US2004/025547, filed on Aug. 5, 2004, which are all incorporated herein by reference.

According to this embodiment, the switch 28A is created and placed over the left side of the text object. The size and shape of the switch 28A is somewhat arbitrary. In other words, the switch 28A could perfectly match the outer perimeter of the text object or it could extend some distance beyond the text object's perimeter or a combination of the two. Similarly, the second switch 28B is placed over the text object's right side, constructed such that its left side does not adjoin the right side of the other invisible switch 28A.

In another embodiment, the left-hand and right-hand areas 24A and 24B of the “volume” text control 18 are implemented as invisible switches 30A and 30B under the text characters, as shown in FIG. 3B. However, in this embodiment, the left and right switches 30A and 30B are positioned such that the right side of the left switch joins the left side of the right switch. Thus, no space exists between the switches 30A and 30B. The text in this text control has an added property, namely, that it is “touch transparent” to a left mouse click. This means that if a user left-clicks anywhere on this text, either switch 30A or 30B will be activated, depending upon where on the text the user has left-clicked. However, if a user right-clicks on the text, an Info Canvas object will appear onscreen for the text object 18.

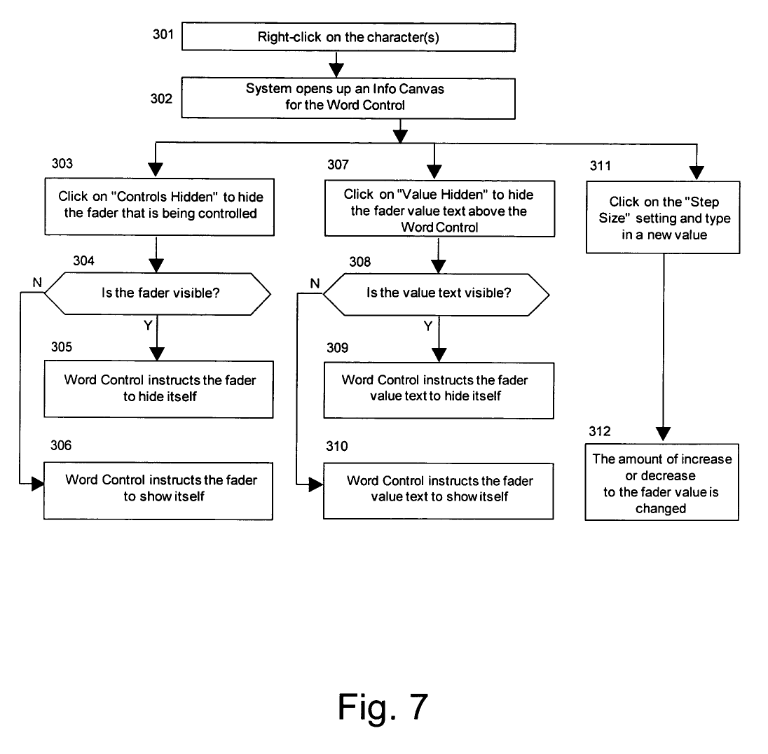

Furthermore, the edge region of the “left-touch transparent” text can be made to be right-touch transparent. So if a user right-clicks on the edge (on or about the perimeter line) of the text, an Info Canvas object will appear for one of the invisible switches below the text. But if a user right-clicks in the middle area of the text, the Info Canvas object for the text will appear onscreen. Again, left-clicking anywhere on the text will result in activating one of the invisible switches below the text. Note: this operation could be reversed and the switches could be placed over the text. In this configuration, the switches would be right-touch transparent on their edges so the user could access the Info Canvas object for the text below them. For more information, see the discussion below pertaining to FIG. 6.

The different constructions and operations of the “volume” text control 18 described above are also applicable to the text control created using “known” characters, such as the “bright” text control 10 of FIG. 1.

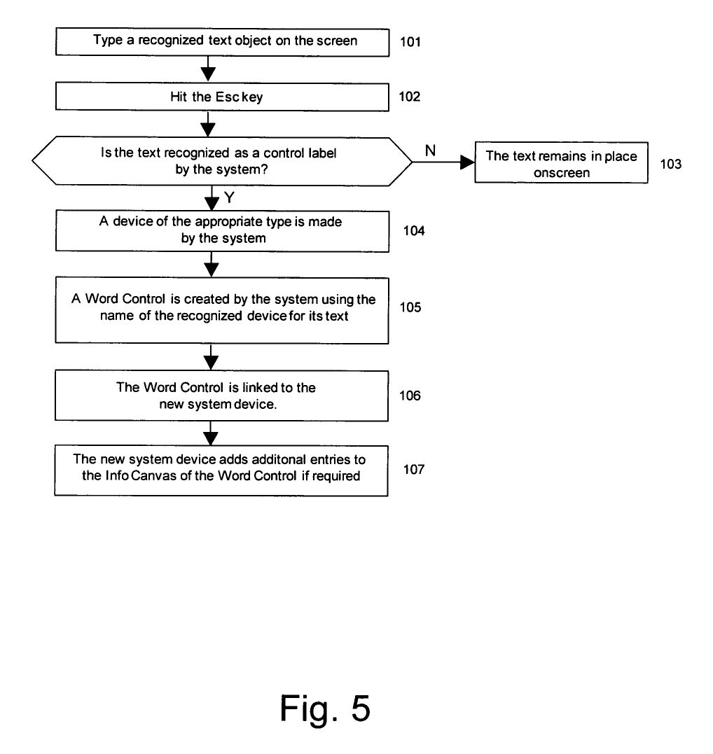

Turning now to FIG. 4A, the Info Canvas object 32 for the “volume” text control 18 in accordance with an embodiment of the invention is shown. In this Info Canvas object 32 is a Category called: “Word Controls.” Under this category are three entries entitled:

a. Controls hidden. This hides the control device, e.g., fader, knob, joystick, switch, and the like (“fader”) that is being controlled by the text object.

b. Value Hidden. This hides the numerical parameter that appears as a number above the text object control. This parameter can be left-clicked on and dragged to any location in the Blackspace environment and still remain operational.

c. Step Size. The default is “1.00”. This means that for every left-click the fader will move a value of 1. If this is changed to “0.01”, the fader moves by a factor of 0.01 or 1/100th. This enables a user to rescale the operation or the “left-clicking” on their word control or text control, which is controlling the operation of a fader that is, in turn, controlling something in the Blackspace environment.

Turning now to FIG. 4B, the Info Canvas object 34 for the “bright” text control 10 of FIG. 1 in accordance with an embodiment of the invention is shown. In this Info Canvas object 34 is a Category called: “Bright Controls.” Under this category are two entries entitled:

a. Frequency 1000.00 Hz. This is the default setting for the frequency of the bright control. The frequency value can be changed by the user by entering a new value.

b. Db 's per click: 6.00 dB. This is the default setting for the decibels per click on the “bright” text control 10. The dB per click value can also be changed by the user by entering a new value.

Note: in case of the text control, it is generally assigned to control a single fader's operation. In the case of a bright control, this fader would likely be the fader that controls the boost/cut function for an equalizer. By changing the frequency, as described under “a” above, this has the effect of changing the EQ frequency band for an equalizer. Changing the “Db's per click” changes the amount of boost or cut that will result from each left-click on the text control.

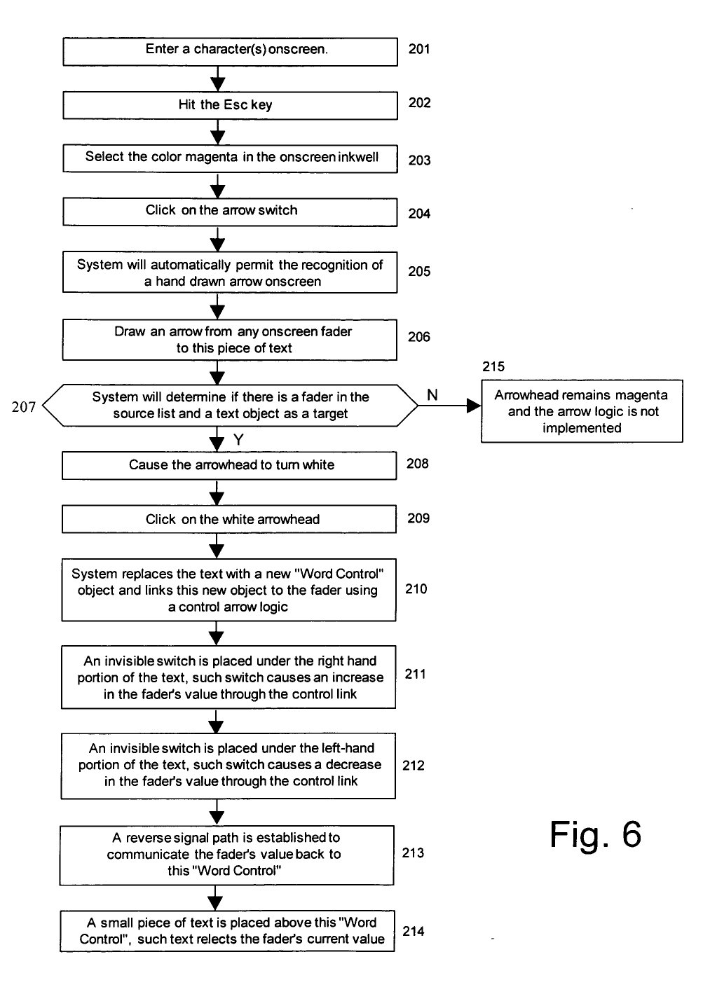

With reference to FIG. 5, the process of creating a text control in accordance with an embodiment of the invention is described. This text control is a defined object in the software and is not created by the user. That is, the text characters used to create the text control is predefined in the software.

Block 101. The user types a recognized text object onscreen. For example, the user could type the word: “Bright.”

Block 102. Then the user hits the Esc key or its equivalent.

Block 103. The software checks to see if this text is known to the system. In other words, is this text object recognized as representing some action, function, property or the like?

Block 104. If no, the text remains onscreen where it was typed and nothing further happens.

Block 105. If yes, a device that is associated with the text object that was typed under block 101 is created by the software. For example, in the case of typing the word: “Bright,” the software could create an equalizer that adjusts the high frequency for a sound file.

Block 106. A Word Control is a graphical object which has up and down nudge capability and can be used to control the operation of another system object. See the flowcharts of FIGS. 6, 9 and 12.

7. The up/down nudge operations are used to control the main parameter of the newly created system device. See the flowcharts of FIGS. 6, 9 and 12.

8. New entries are added to the Info Canvas object of the Word Control if they are required. Such entries may include “Hidden Controls,” which enables a user to hide the operational controls for the Word Control.

With reference to FIG. 6, the process of creating a Word Control with invisible switches placed under the word control text characters in accordance with an embodiment of the invention is described. The flow chart describes the implementation of the magenta “Word Control” arrow logic. This logic is designed to permit a user to use simple graphical means to program text, including letters, numbers, and other characters, to control the value of a device linked to that text. In this discussion and flowchart, the term “fader” is used to represent any onscreen device which has a continuously adjustable property which can be adjusted or viewed by the user. Another example of such a device might be a knob.

Block 201. A user inputs, e.g., types, character(s) onscreen. Typically, these character(s) would be a word or phrase that would describe the type of process that is desired to be controlled. For instance, a user may input the phrase: “boost/cut.” This describes a control in an audio equalizer that adjusts the level of a certain frequency for a sound file.

Block 202. After inputting the desired character(s), the user hits the Esc key or its equivalent to enter the character(s) into the software.

Block 203. The color magenta is selected in an inkwell. The software supports multiple inkwells. The onscreen inkwell typically has a smaller number of easy to recognize colors that are named for easy reference. Magenta is one of these colors.

Block 204. The user activates the arrow switch or its equivalent. One method of activating the arrow switch is to left-click on it. Another method would be to use a verbal command. Another method could be using a gesture command.

Block 205. When the arrow switch is activated, this activates the arrow recognition mode. This mode permits the software to recognize certain types of user drawn input as arrows.

Block 206. A user draws an arrow where its tail intersects, nearly intersects or encircles (“intersects”) a device, e.g., a fader, and the head of this arrow intersects the character(s) entered in block 201.

Block 207. The software determines if there is a fader in the source list and a text object—“character(s)”—in the target object list of the drawn and recognized magenta arrow.

Block 215. If no, then the arrowhead remains the color magenta and no arrow logic is implemented, because the arrow logic is not valid. It's not valid because it needs a valid target object and it can't find one, as there is no valid device in the target object list for the drawn and recognized magenta arrow.

Block 208. If yes, the software causes the magenta arrowhead to turn white. This indicates to the user that the magenta arrow logic is valid. It also gives the user the opportunity to choose to either activate the arrow logic or not activate it.

Block 209. The user clicks on the white arrowhead. This activates the arrow logic for the drawn and recognized magenta arrow.

Block 210. The software replaces the text “character(s)” with a new Word Control object and links this new object to the device which the magenta arrow's tail intersected and which is now in the target list of this arrow. In this example, this device is a fader. This fader is linked to the Word Control via a “control from” arrow logic.

The text characters in the new Word Control are instructed to reject left mouse clicks, so that when the main mouse handling software looks to find which object has been clicked on, then it will ignore the text characters themselves and find any object underneath instead. The way this feature could work is that the text characters in the new Word Control would recognize the Word Control itself as a context that enables the rejection of left-mouse clicks (or any type of desired mouse click) made on that text.

Block 211. An invisible switch is created and placed under the right-hand portion of the character(s) created at block 201. When this invisible switch is activated, it causes an increase in the fader's value through the established control link.

Block 212. An invisible switch is created and placed under the left-hand portion of the character(s) created under at block 201. When this invisible switch is activated, it causes a decrease in the fader's value through the established control link.

Note: regarding both invisible switches, they are placed under the character(s) created at block 201. This means that a special condition is created for these characters that enables them to be touch transparent for a left-click only. In other words, when the text is left-clicked on, the mouse click is transferred through the text object “character(s)” to the invisible switch below in order to activate that switch. In the context of a Word Control, the characters that are on top of the invisible switches take on a special function, which enables a mouse click to be transferred through them to the switch below them. See at block 210.

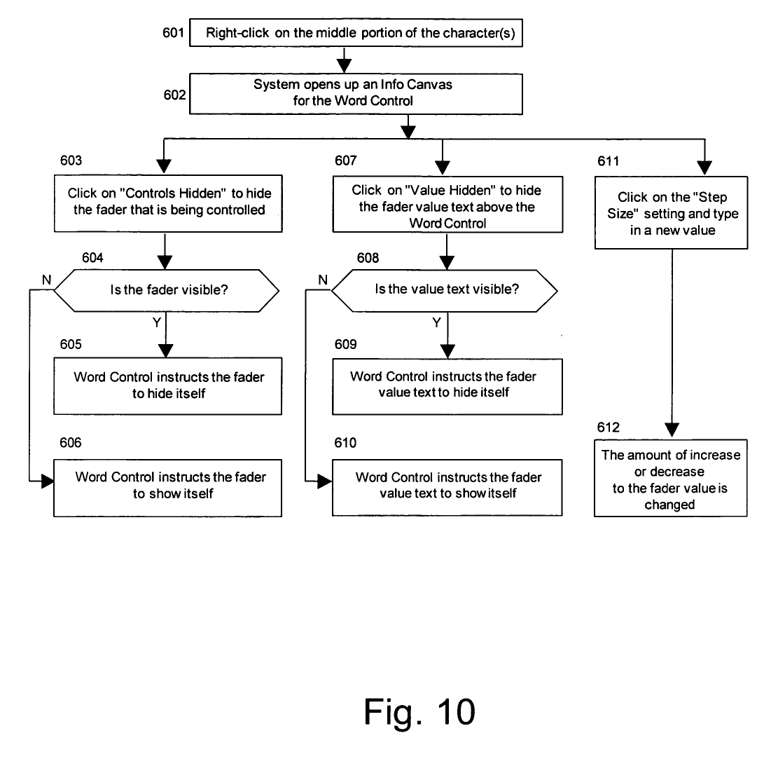

Note: An alternative strategy to blocks 211 and 212 might be to place the invisible switches on top of the Word Control's text characters, leaving a space between them for the main mouse handling software to access the text characters directly. This is described with reference to the flowchart of FIG. 9.

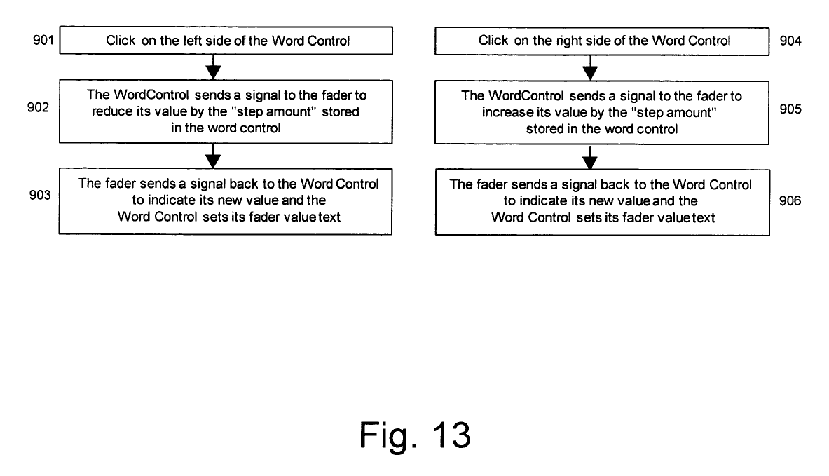

Note: Another alternative strategy to blocks 211 and 212 might be to define two graphical areas within the text characters themselves. In this case the text characters would not ignore mouse left clicks. When the Word Control receives a left click event from the mouse handling software it could work out that it was within one of these two areas and cause the same effects as described in blocks 211 and 212. This is described with reference to the flowchart of FIG. 12.

Block 113. A reverse signal path is established to communicate the fader's value back to the Word Control. This way any change in the fader's value is notified back to the Word Control. In other words, a message informing the Word Control of a change in the fader's value is transmitted back to the Word Control.

Block 114. A piece of text or its equivalent is placed near the Word Control. This text reflects the fader's current value. Furthermore, this text is a mirror of the fader's value. Therefore, as the fader's value changes so does the value shown in this text. This text can be a numerical display of some kind.

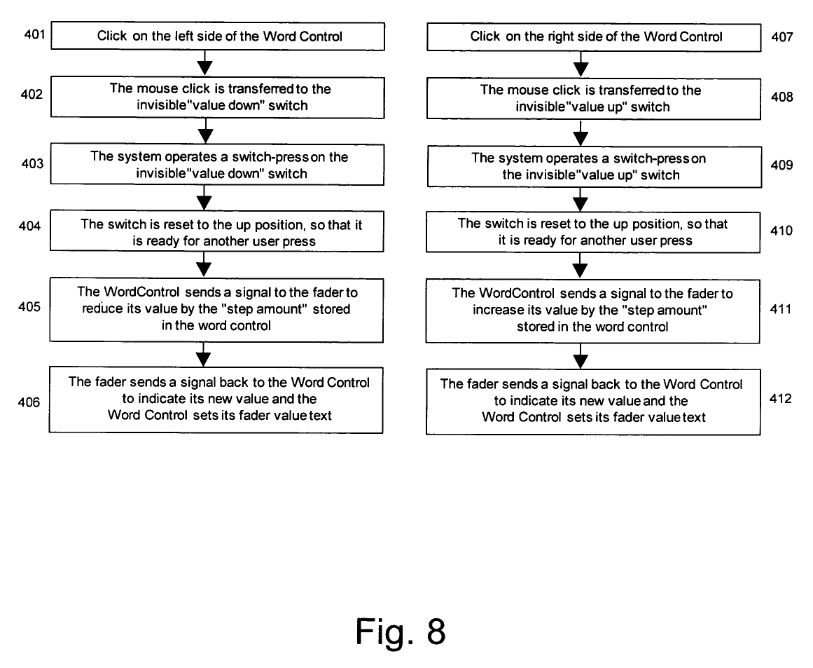

With reference to FIG. 7, the process of setting up a Word Control with invisible switches placed under the word control text characters, after it has been created by a valid magenta arrow logic, in accordance with an embodiment of the invention is described.

Block 301. A user right-clicks on the character(s).

Block 302. The software shows an Info Canvas object for this text object (“character(s)”) onscreen.

Block 303. Various entries are dynamically added to this Info Canvas object after the successful activation of the magenta arrow logic for these character(s).

Three of these entries are presented in this flowchart in three columns under block 302. The first of these entries is “Controls Hidden”. The user clicks on this entry.

Block 304. The software checks to see if the device linked to the character(s) is visible.

Block 305. If yes, then the Word Control instructs the device to become invisible.

Block 306. If no, then the Word Control instructs the device to show itself.

Block 307. Continuing from block 302, another dynamic entry is “Value Hidden.” This entry is selected.

Block 308. The software checks to see if this value text is visible. The “value text” is an additional piece of text associated with the Word Control, which displays the setting or other data about the device that the Word Control is controlling. This could be the value of a fader position.

Block 309. If yes, then the Word Control instructs the value text to become hidden.

Block 310. If no, then the Word Control instructs the value text to become visible onscreen.

Block 311. Continuing again block 302, the third dynamic entry is “Step Size.” This entry is selected.

Block 312. The “Step Size” entry permits a user to change the size of the steps, the amount that the device's value will be changed, each time one of the invisible switches linked to this device is activated. This step size is preserved as a property of the Word Control. Let's say the device is a fader, then by increasing the “Step Size,” the amount of change for the fader cap of the fader device will be increased. So each time a user activates the right invisible switch for the character(s) linked to this fader, the fader's cap will move by a larger distance. The same will be true for when activating the left invisible switch linked to this fader device. Likewise, if the “Step Size” is decreased, this will cause a smaller change in the fader's cap (and therefore in the amount of value change for the fader) when either invisible switch linked to this fader is activated.

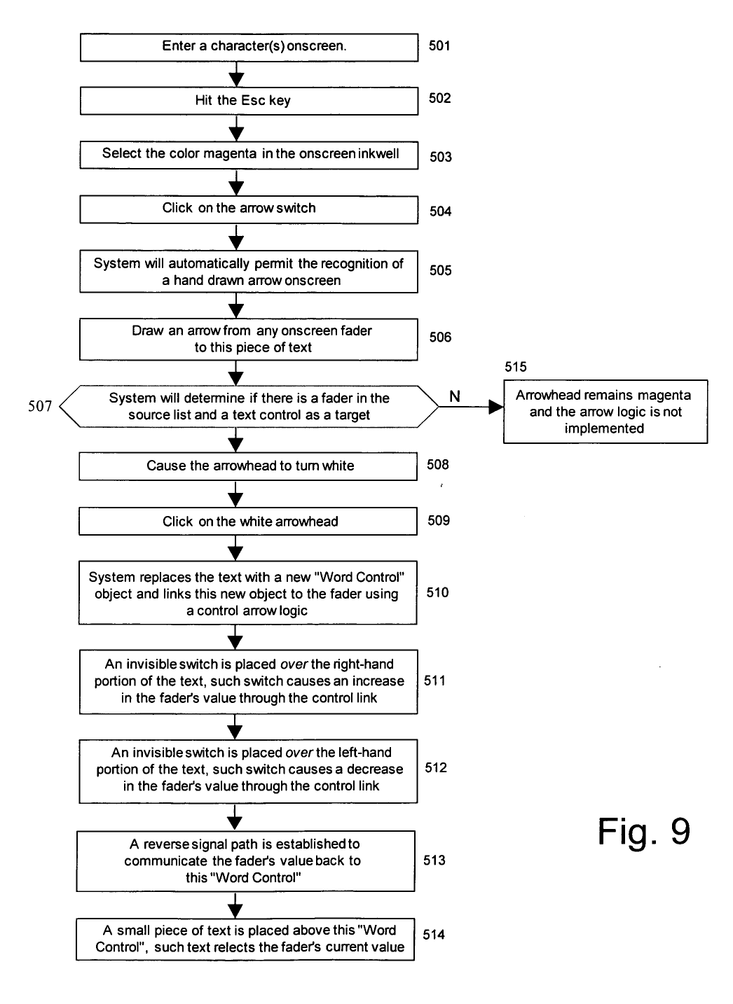

With reference to FIG. 8, the process of using a Word Control with invisible switches placed under the word control text characters in accordance with an embodiment of the invention is described.

Block 401. A user activates the left side of a Word Control, e.g., by left-clicking on it.

Block 402. The mouse click is transferred to the invisible switch under the character(s), as created at block 201 of the flowchart of FIG. 6.

Block 403. The software operates a switch-press on the invisible “value down” switch. This is the invisible switch located on the left side of the character(s).

Block 404. The switch is reset to the up position, so that it is ready for another user press. This means that the switch is a momentary switch, as opposed to being a latching switch. As a momentary switch, each time the switch is activated (left-clicked on or its equivalent), upon the mouse up-click, the switch is automatically reset to an off status.

Block 405. The Word Control sends a signal to the controlled device to reduce its value by the “step size” stored in the Word Control. The setting for the “Step Size” in the Info Canvas object for the character(s), as created at block 201 of the flowchart of FIG. 6, determines the amount of reduction for the fader's value when the invisible “value down” switch is activated.

Block 406. The controlled device sends a signal back to the Word Control to indicate its new value and the Word Control sets its fader value text accordingly. When the Word Control receives a signal from the device linked to it (e.g., a fader), the Word Control changes the “value text” near the character(s) to match the device's new value (in this case, the new value for the fader).

Block 407. A user activates the right side of a Word Control, e.g., by left-clicking on it.

Block 408. The mouse click is transferred to the invisible switch under the character(s) as created at block 201 of the flowchart of FIG. 6.

Block 409. The software operates a switch-press on the invisible “value up” switch. This is the invisible switch located on the right side of the character(s).

Block 410. The switch is reset to the up position, so that it is ready for another user press. This means that the switch is a momentary switch, as opposed to being a latching switch. As a momentary switch, each time the switch is activated (left-clicked on or its equivalent), upon the mouse up-click, the switch is automatically reset to an off status.

Block 411. The Word Control sends a signal to the controlled device to increase its value by the “step size” stored in the Word Control. The setting for the “Step Size” in the Info Canvas object for the character(s), as created at block 201 of the flowchart of FIG. 6, determines the amount of increase for the fader's value when the invisible “value up” switch is activated.

Block 412. The controlled device sends a signal back to the Word Control to indicate its new value and the Word Control sets its fader value text accordingly. When the Word Control receives a signal from the device linked to it (e.g., a fader), the Word Control changes the “value text” near the character(s) to match the device's new value (in this case, the new value for the fader).

With reference to FIG. 9, the process of creating a Word Control with invisible switches placed over the word control text characters with a space between the two switches, as illustrated in FIG. 3A, in accordance with an embodiment of the invention is described. The flowchart of FIG. 9 is the same as the flowchart of FIG. 6, except for blocks 511 and 512, which correspond to blocks 211 and 212 of the flowchart of FIG. 6. Thus, only blocks 511 and 512 are described below. In this flow chart of FIG. 9, the invisible switches are placed on top of the character(s), instead of under them.

Block 511. An invisible switch is place over the right-hand portion of the character(s). This switch causes an increase in the fader's (or other suitable linked device) through the control link.

Block 512. An invisible switch is place over the left-hand portion of the character(s) of step 1. This switch causes a decrease in the fader's (or other suitable linked device) through the control link.

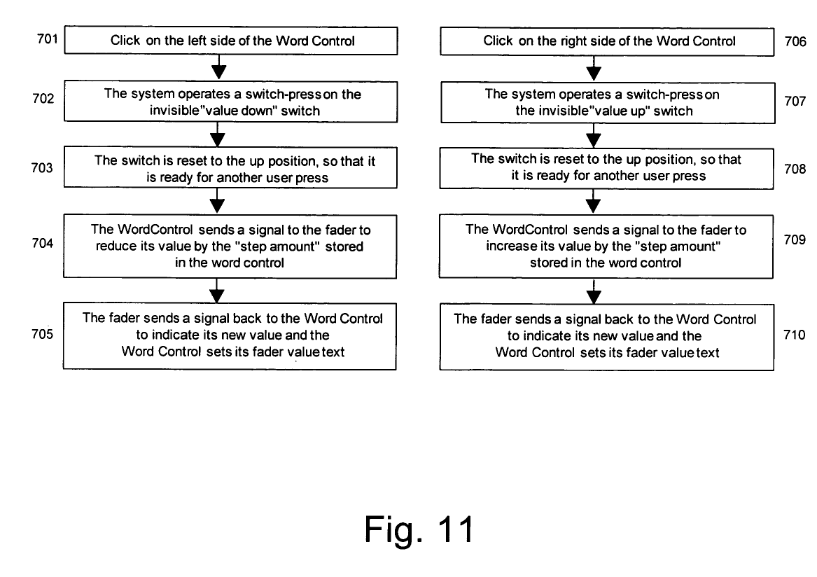

With reference to FIG. 10, the process of setting up a Word Control with invisible switches placed over the word control text characters, after it has been created by a valid magenta arrow logic, in accordance with an embodiment of the invention is described.

Block 601. A user right-clicks on the middle portion of the character(s). The invisible switches, which have been placed on top of these character(s) have been placed in such a manner as to leave a space between them, which exposes the middle portion of the character(s). Here is an area not covered with an invisible switch. This area is of an arbitrary size as the invisible switches themselves are of an arbitrary size.

Block 602. The software shows an Info Canvas object for this text object (“character(s)”) onscreen.

Block 603. Various entries are dynamically added to this Info Canvas object after the successful activation of the magenta arrow logic for these character(s).

Three of these entries are presented in this flowchart in three columns under block 602. The first of these entries is “Controls Hidden”. The user clicks on this entry.

Block 604. The software checks to see if the device linked to the character(s) is visible.

Block 605. If yes, then the Word Control instructs the device to become invisible.

Block 606. If no, then the Word Control instructs the device to show itself.

Block 607. Continuing from block 602, another dynamic entry is “Value Hidden.” This entry is selected.

Block 608. The software checks to see if this value text is visible. The “value text” is an additional piece of text associated with the Word Control, which displays the setting or other data about the device that the Word Control is controlling. This could be the value of a fader position.

Block 609. If yes, then the Word Control instructs the value text to become hidden.

Block 610. If no, then the Word Control instructs the value text to become visible onscreen.

Block 611. Continuing again from block 602, the third dynamic entry is “Step Size.” This entry is selected.

Block 612. The “Step Size” entry permits a user to change the size of the steps, the amount that the device's value will be changed, each time one of the invisible switches linked to this device is activated. This step size is preserved as a property of the Word Control. Let's say the device is a fader, then by increasing the “Step Size,” the amount of change for the fader cap of the fader device will be increased. So each time a user activates the right invisible switch for the character(s) linked to this fader, the fader's cap will move by a larger distance. The same will be true for when activating the left invisible switch linked to this fader device. Likewise, if the “Step Size” is decreased, this will cause a smaller change in the fader's cap (and therefore in the amount of value change for the fader) when either invisible switch linked to this fader is activated.

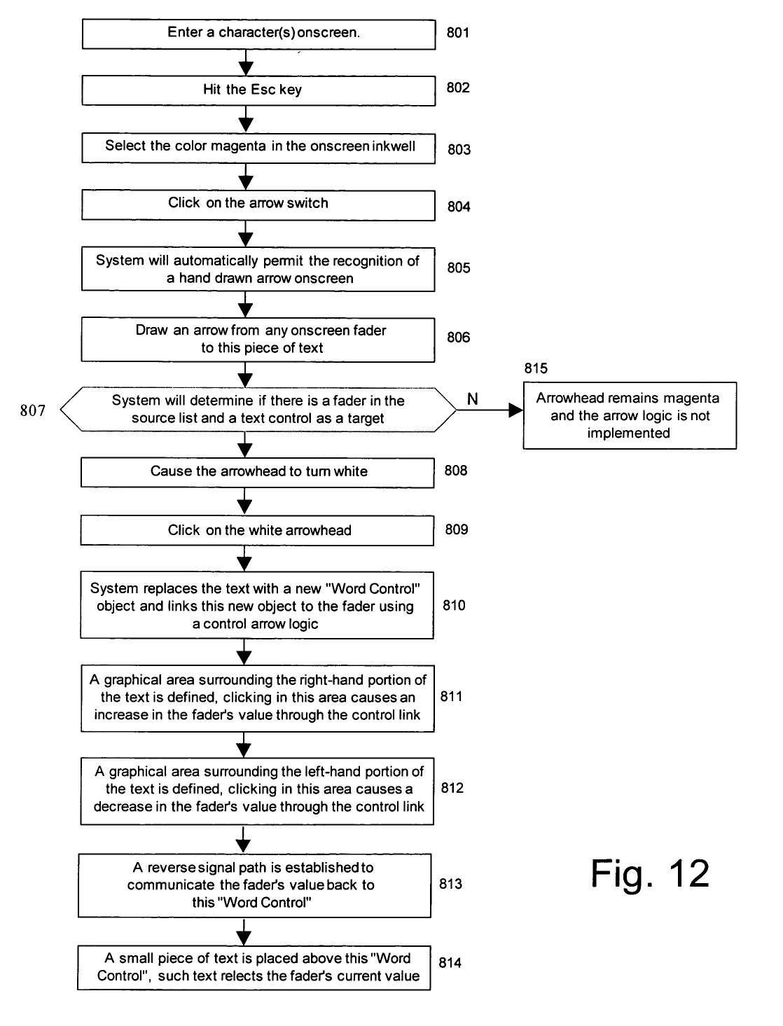

With reference to FIG. 11, the process of using a Word Control with invisible switches placed over the word control text characters in accordance with an embodiment of the invention is described.

Block 701. A user activates the left side of a Word Control, e.g., by left-clicking on it.

Block 702. The software operates a switch-press on the invisible “value down” switch. This is the invisible switch located on the left side of the character(s).

Block 703. The switch is reset to the up position, so that it is ready for another user press. This means that the switch is a momentary switch, as opposed to being a latching switch. As a momentary switch, each time the switch is activated (left-clicked on or its equivalent), upon the mouse up-click, the switch is automatically reset to an off status.

Block 704. The Word Control sends a signal to the controlled device to reduce its value by the “step size” stored in the Word Control. The setting for the “Step Size” in the Info Canvas object for the character(s), as created at block 501 of the flowchart of FIG. 9, determines the amount of reduction for the fader's value when the invisible “value down” switch is activated.

Block 705. The controlled device sends a signal back to the Word Control to indicate its new value and the Word Control sets its fader value text accordingly. When the Word Control receives a signal from the device linked to it (e.g., a fader), the Word Control changes the “value text” near the character(s) to match the device's new value (in this case, the new value for the fader).

Block 706. A user activates the right side of a Word Control, e.g., by left-clicking on it.

Block 707. The software operates a switch-press on the invisible “value up” switch. This is the invisible switch located on the left side of the character(s).

Block 708. The switch is reset to the up position, so that it is ready for another user press. This means that the switch is a momentary switch, as opposed to being a latching switch. As a momentary switch, each time the switch is activated (left-clicked on or its equivalent), upon the mouse up-click, the switch is automatically reset to an off status.

Block 709. The Word Control sends a signal to the controlled device to increase its value by the “step size” stored in the Word Control. The setting for the “Step Size” in the Info Canvas for the character(s), as created at block 501 of the flowchart of FIG. 9, determines the amount of increase for the fader's value when the invisible “value up” switch is activated.

Block 710. The controlled device sends a signal back to the Word Control to indicate its new value and the Word Control sets its fader value text accordingly. When the Word Control receives a signal from the device linked to it (e.g., a fader), the Word Control changes the “value text” near the character(s) to match the device's new value (in this case, the new value for the fader).

With reference to FIG. 12, the process of creating a Word Control without invisible switches in accordance with an embodiment of the invention is described. The flowchart of FIG. 12 is the same as the flowchart of FIG. 6, except for blocks 811 and 812, which correspond to blocks 211 and 212 of the flowchart of FIG. 6. Thus, only blocks 811 and 812 are described below. In this flow chart of FIG. 12, no invisible switches are created.

Block 811. The dimensions of the text are analyzed and an area representing the right-hand part of this text's geometry is defined as representing the “up” operation for the Word Control.

Block 813. The dimensions of the text are analyzed and an area representing the left-hand part of this text's geometry is defined as representing the “down” operation for the Word Control.

Note; the right and left-hand part of the text's geometry is an arbitrary proportion of the overall text geometry and can be set to any desired size. This can be set either as a software default or it can be set by the user, by means of an entry with variable parameters in the Info Canvas object for the text.

The process of setting up a Word Control without invisible switches in accordance with an embodiment of the invention is the same as the process of setting up a Word Control with invisible switches placed under the word control text characters, which was described above with reference to FIG. 7.

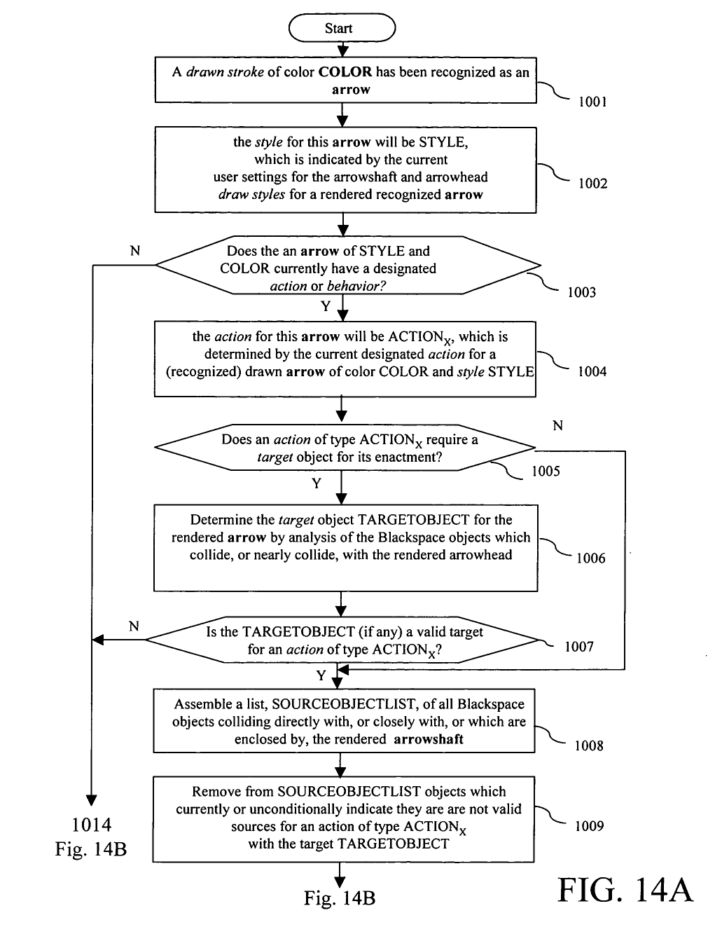

With reference to FIG. 13, the process of setting up a Word Control without invisible switches, after it has been created by a valid magenta arrow logic, in accordance with an embodiment of the invention is described. This flowchart shows how the same functionality can be achieved without using invisible switches. In this discussion and flowchart, the term “fader” is used to represent any onscreen device which has a continuously adjustable property which can be adjusted or viewed by the user. Another example of such a device might be a knob.

Block 901. A user activates the left side of a Word Control, e.g., by left-clicking on it. When the mouse press event is received from the main mouse handling software the position of the event is determined to be in the “down” area which was defined when the Word Control was created.

Block 902. The Word Control sends a signal to the fader to reduce its value by the “step size” stored in the Word Control. The setting for the “Step Size” in the Info Canvas object for the character(s), as created in block 801 of the flowchart of FIG. 12, determines the amount of reduction for the fader's value when the invisible “value down” switch is activated.

Block 903. The fader sends a signal back to the Word Control to indicate its new value and the Word Control sets its fader value text accordingly. When the Word Control receives a signal from the device linked to it (e.g., a fader), the Word Control changes the “value text” near the character(s) to match the device's new value (in this case, the new value for the fader).

Block 904. A user activates the right side of a Word Control, e.g., by left-clicking on it. When the mouse press event is received from the main mouse handling software, the position of the event is determined to be in the “up” area, which was defined when the Word Control was created.

Block 905. The Word Control sends a signal to the fader to increase its value by the “step size” stored in the Word Control. The setting for the “Step Size” in the Info Canvas object for the character(s), as created in block 801 of the flowchart of FIG. 12, determines the amount of increase for the fader's value when the invisible “value up” switch is activated.

Block 906. The fader sends a signal back to the Word Control to indicate its new value and the Word Control sets its value text accordingly. When the Word Control receives a signal from the device linked to it (e.g., a fader), the Word Control changes the “value text” near the character(s) to match the device's new value (in this case, the new value for the fader).

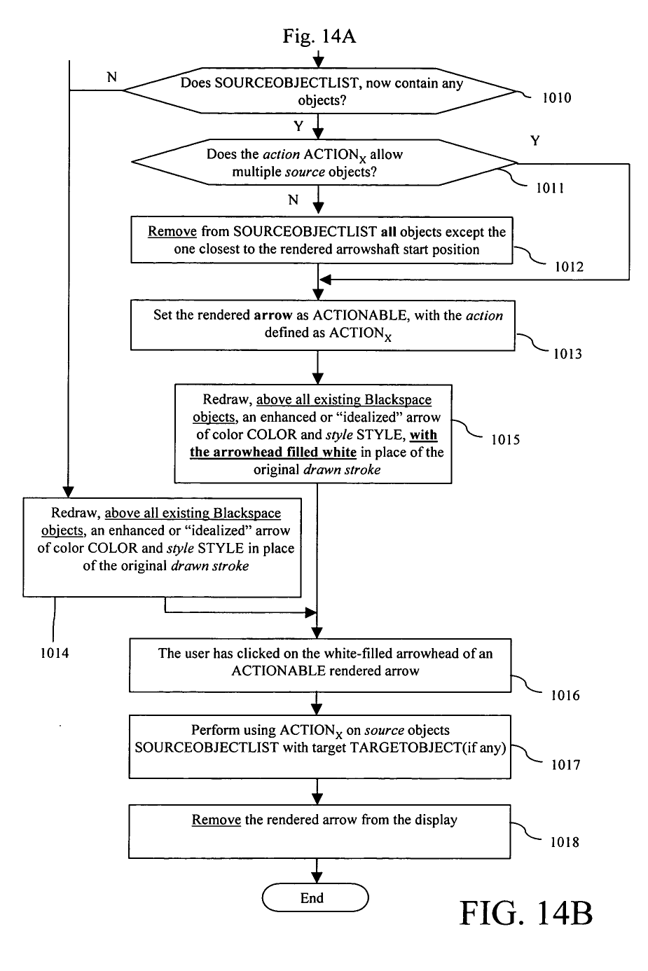

With reference to the flowchart of FIGS. 14A and 14B, the process for drawing an arrow in Blackspace environment and applying an arrow logic in accordance with an embodiment of the invention is now described.

Block 1001. A drawn stroke of color “COLOR” has been recognized as an arrow—a mouse down has occurred, a drawn stroke (one or more mouse movements) has occurred, and a mouse up has occurred. This stroke is of a user-chosen color. The color is one of the factors that determine the action (“arrow logic”) of the arrow. In other words, a red arrow can have one type of action (behavior) and a yellow arrow can have another type of action (behavior) assigned to it.

Block 1002. The style for this arrow will be “STYLE”—This is a user-defined parameter for the type of line used to draw the arrow. Types include: dashed, dotted, slotted, shaded, 3D, etc.

Block 1003. Does an arrow of STYLE and COLOR currently have a designated action or behavior? This is a test to see if an arrow logic has been created for a given color and/or line style. The software searches for a match to the style and color of the drawn arrow to determine if a behavior can be found that has been designated for that color and/or line style. This designation can be a software default or a user-defined parameter.

If the answer to Block 1003 is yes, the process proceeds to Block 1004. If no, the process proceeds to Block 1014.

Block 1004. The action for this arrow will be ACTION_{X}, which is determined by the current designated action for a recognized drawn arrow of COLOR and STYLE. If the arrow of STYLE and COLOR does currently have a designated action or behavior, namely, there is an action for this arrow, then the software looks up the available actions and determines that such an action exists (is provided for in the software) for this color and/or style of line when used to draw a recognized arrow. In this step the action of this arrow is determined.

Block 1005. Does an action of type ACTION_{X} require a target object for its enactment? The arrow logic for any valid recognized arrow includes as part of the logic a determination of the type(s) and quantities of objects that the arrow logic can be applied to after the recognition of the drawn arrow. This determination of type(s) and quantities of objects is a context for the drawn arrow, which is recognized by the software.

### EXAMPLE 1

Let's say a red arrow is drawn between four (4) faders such that the arrow intersects all four faders. Let's further say the red arrow logic is a “control logic,” namely, the arrow permits the object that it's drawn from to control the object that it's drawn to. Therefore, with this arrow logic of the red arrow, a target is required. Furthermore, the first intersected fader will control the last intersected fader and the faders in between will be ignored. See Blocks 1011 and 1012 in this flow chart.

### EXAMPLE 2

Let's say a yellow arrow is drawn between four faders, such that the arrow shaft intersects the first three faders and the tip of the arrow intersects the fourth fader. Let's further say that an “assignment” arrow logic is designated for the color yellow, namely, “every object that the arrow intersects will be assigned to the object that arrow points to.” In this case, the arrow logic will be invalid, as a fader cannot be assigned to another fader according to this logic. Whereas, if the same yellow arrow is drawn to intersect four faders and the arrowhead is made to intersect a blue star, the four faders will be assigned to the star.

The behavior of the blue star will be governed by the yellow arrow logic. In this instance, the four faders will disappear from the screen and, from this point on, have their screen presence be determined by the status of the blue star. In other words, they will reappear in their same positions when the blue star is clicked on and then disappear again when the blue star is clicked once more and so on. Furthermore, the behavior of the faders will not be altered by their assignment to the blue star. They still exist on the Global drawing surface as they did before with their same properties and functionality, but they can be hidden by clicking on the blue star to which they have been assigned. Finally, they can be moved to any new location while they are visible and their assignment to the blue star remains intact.

### EXAMPLE 3

Let's say you draw a green arrow which has a “copy” logic assigned to it, which states, “copy the object(s) that the arrow shaft intersects or encircled to the point on the Global Drawing surface (Blackspace) that the tip of the arrowhead points to”. Because of the nature of this arrow logic, no target object is required. What will happen is that the object(s) intersected or encircled by the green arrow will be copied to another location on the Global Drawing surface.

If the answer to Block 1005 is yes, the process proceeds to Block 1006. If no, the process proceeds to Block 1008.

Block 1006. Determine the target object TARGETOBJECT for the rendered arrow by analysis of the Blackspace objects which collide or nearly collide with the rendered arrowhead. The software looks at the position of the arrowhead on the global drawing surface and determines which objects, if any, collide with it. The determination of a collision can be set in the software to require an actual intersection or distance from the tip of the arrowhead to the edge of an object that is deemed to be a collision. Furthermore, if no directly colliding objects are found, preference may or not be given to objects which do not collide in close proximity, but which are near to the arrowhead, and are more closely aligned to the direction of the arrowhead than other surrounding objects. In other words, objects which are situated on the axis of the arrowhead may be chosen as targets even though they don't meet a strict “collision” requirement. In all cases, if there is potential conflict as to which object to designate as the target, the object with the highest object layer will be designated. The object with the highest layer is defined as the object that can overlap and overdraw other objects that it intersects.

Block 1007. Is the target object (if any) a valid target for an action of the type ACTION_{X}? This step determines if the target object(s) can have the arrow logic (that belongs to the line which has been drawn as an arrow and recognized as such by the software) applied to it. Certain arrow logics require certain types of targets. As mentioned above, a “copy” logic (green arrow) does not require a target. A “control” logic (red arrow) recognizes only the object to which the tip of the arrow is intersecting or nearly intersecting as its target.

If the answer to Block 1007 is yes, the process proceeds to Block 1008. If no, the process proceeds to Block 1010.

Block 1008. Assemble a list, SOURCEOBJECTLIST, of all Blackspace objects colliding directly with, or closely with, or which are enclosed by, the rendered arrowshaft. This list includes all objects as they exist on the global drawing surface that are intersected or encircled by or nearly intersected by the drawn and recognized arrow object. They are placed in a list in memory, called for example, the “source object list” for this recognized and rendered arrow.

Block 1009. Remove from SOURCEOBJECTLIST, objects which currently or unconditionally indicate they are not valid sources for an action of type ACTION_{X} with the target TARGETOBJECT. Different arrow logics have different conditions in which they recognize objects that they determine as being valid sources for their arrow logic. The software analyzes all source objects on this list and then evaluates each listed object according to the implementation of the arrow logic to these sources and to the target(s), if any. All source objects which are not valid sources for a given arrow logic, which has been drawn between that object and a target object, will be removed from this list.

Block 1010. Does SOURCEOBJECTLIST now contain any objects? If any source objects qualify as being valid for the type of arrow logic belonging to the drawn and recognized arrow that intersected or nearly intersected them, and such logic is valid for the type of target object(s) intersected by this arrow, then these source objects will remain in the sourceobjectlist.

If the answer to Block 1010 is yes, the process proceeds to Block 1011. If no, the process proceeds to Block 1014.

Block 1011. Does the action “ACTION_{X}” allow multiple source objects? A test is done to query the type of arrow logic belonging to the drawn and recognized arrow to determine if the action of its arrow logic permits multiple source objects to be intersected or nearly intersected by its shaft.

If the answer to Block 1011 is yes, the process proceeds to Block 1013. If no, the process proceeds to Block 1012.

Block 1012. Remove from SOURCEOBJECTLIST all objects except the one closest to the rendered arrowshaft start position. In this case, the recognized arrow logic can have only a single source. So the software determines that the colliding object which is closest to the drawn and recognized arrow's start position is the source object and then removes all other source objects that collide with its shaft.

NOTE: Certain types of arrow logics require certain types of sources. For instance, if a red “control” arrow is drawn to intersect four switches and then drawn to point to blank Blackspace surface (an area on the global drawing surface where no objects exist), then no valid sources will exist and no arrow logic will be applied. The “red” logic will be considered invalid. It's invalid because although the source objects are correct for this type of arrow logic, a suitable target object must exist for the “control” logic to be valid in the absence of a context that would override this requirement. If however, this same red arrow is drawn to intersect these same four switches and then the tip of the arrow also intersects or nearly intersects a fifth switch (a valid target for this logic), then the red arrow logic recognizes the first intersected switch only as its source and the last intersected switch only as the target. The other intersected switches that appeared on the “sourceobjectlist” will be removed.

Block 1013. Set the rendered arrow as Actionable with the action defined as ACTION_{X}. After Block 1012, the required action has been identified and has not been immediately implemented because it awaits an input from a user. As an example, identifying the action would be to have the arrowhead of the drawn and recognized arrow turn white (see Block 1015). An example of input from a user would be requiring them to click on the white arrowhead to activate the logic of the drawn and recognized arrow (see Blocks 1015-1018).

Block 1014. Redraw above all existing Blackspace objects an enhanced or “idealized” arrow of COLOR and STYLE in place of the original drawn stroke. If an arrow logic is not deemed to be valid for any reason, the drawn arrow is still recognized, but rendered onscreen as a graphic object only. The rendering of this arrow object includes the redrawing of it by the software in an idealized form as a computer generated arrow with a shaft and arrow head equaling the color and line style that were used to draw the arrow.

Block 1015. Redraw above all existing Blackspace objects, an enhanced or “idealized” arrow of COLOR and STYLE with the arrowhead filled white in place of the original drawn stroke. After the arrow logic is deemed to be valid for both its source(s) and target object(s), then the arrowhead of the drawn and recognized arrow will turn white. This lets a user decide if they wish to complete the implementation of the arrow logic for the currently designated source object(s) and target object(s).

Block 1016. The user has clicked on the white-filled arrowhead of an Actionable rendered arrow. The user places their mouse cursor over the white arrowhead of the drawn and recognized arrow and then performs a mouse downclick.

Block 1017. Perform using ACTION_{X} on source objects “SOURCEOBJECTLIST” with target “TARGETOBJECT” if any. After receiving a mouse downclick on the white arrowhead, the software performs the action of the arrow logic on the source object(s) and the target object(s) as defined by the arrow logic.

Block 1018. Remove the rendered arrow from the display. After the arrow logic is performed at Block 1017, the arrow is removed from being onscreen and no longer appears on the global drawing surface. This removal is not graphical only. The arrow is removed and no longer exists in time. However, the result of its action being performed on its source and target object(s) remains.

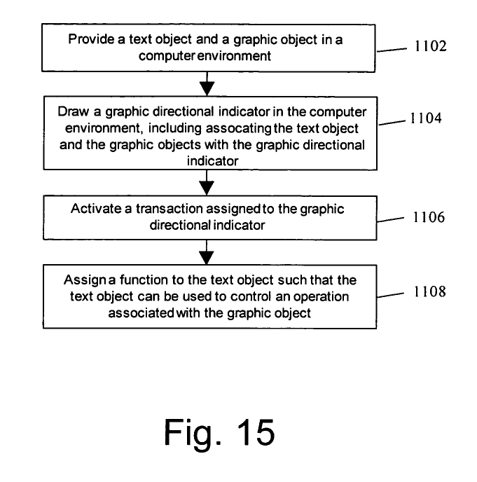

A method for creating and using a control text object in accordance with an embodiment of the invention is described with reference to a flow diagram of FIG. 15. At block 1102, a text object and a graphic object are provided in a computer environment. Next, at block 1104, a graphic directional indicator is drawn in the computer environment. Furthermore, at block 1106, the text object and the graphic object are associated with the graphic directional indicator. Next, at block 1106, the graphic directional indicator is activated. Next, at block 708, a function is assigned to the text object such that the text object can be used to control an operation associated with the graphic object.

An embodiment in accordance with the invention includes a storage medium, readable by a computer, tangibly embodying a program of instructions executable by the computer to perform the method steps for creating and using a control text object.

Although specific embodiments of the invention have been described and illustrated, the invention is not to be limited to the specific forms or arrangements of parts so described and illustrated. The scope of the invention is to be defined by the claims appended hereto and their equivalents.

1. A method for creating and using a control text object; said method comprising:
providing a text object and a graphic object in a computer environment;
drawing a graphic directional indicator in said computer environment, including associating said text object and said graphic object with said graphic directional indicator;
activating a transaction assigned to said graphic directional indicator; and
assigning a function to said text object such that said text object can be used to control an operation associated with said graphic object.

2. A storage medium readable by a computer, tangibly embodying a program of instructions executable by said computer to perform method steps for creating and using a control text object, said method steps comprising:
providing a text object and a graphic object in a computer environment;
drawing a graphic directional indicator in said computer environment, including associating said text object and said graphic object with said graphic directional indicator;
activating a transaction assigned to said graphic directional indicator; and
assigning a function to said text object such that said text object can be used to control an operation associated with said graphic object.
